(19) United States
(12) Patent Application Publication
(10) Pub. No.: US 2025/0343170 A1
(43) Pub. Date: Nov. 6, 2025

(54) PACKAGE CONNECTORS IN SEMICONDUCTOR PACKAGES AND METHODS OF FORMING

(71) Applicant: Taiwan Semiconductor Manufacturing Co., Ltd., Hsinchu (TW)

(72) Inventors: Wei-Hung Lin, Xinfeng Township (TW); Chi-Chun Hsieh, Hsinchu (TW); Ming-Hua Lo, Taoyuan (TW); Chung-Chih Chen, Hsinchu (TW); Hsin-Hsien Wu, Hsinchu (TW)

(21) Appl. No.: 19/265,615

(22) Filed: Jul. 10, 2025

Related U.S. Application Data
(63) Continuation of application No. 18/490,014, filed on Oct. 19, 2023.
(60) Provisional application No. 63/517,365, filed on Aug. 3, 2023.

(51) Int. Cl. H01L 23/00; H01L 23/498; H01L 23/538; H01L 25/065

(52) U.S. Cl. CPC H01L 23/564; H01L 23/49816; H01L 23/5383; H01L 25/0655; H01L 24/16; H01L 24/32; H01L 24/73; H01L 2224/16227; H01L 2224/32225; H01L 2224/73204

(57) ABSTRACT

A package includes a first package component; a second package component bonded to the first package component by a first plurality of solder connectors; and a first plurality of spacer connectors extending from the first package component to the second package component. A diameter of a spacer connector the first plurality of spacer connectors is larger than a height of a solder connector of the first plurality of solder connectors, and the first plurality of spacer connectors comprises a different material than the first plurality of solder connectors.

### PRIORITY CLAIM AND CROSS-REFERENCE

This application is a continuation of U.S. application Ser. No. 18/490,014, filed on Oct. 19, 2023, which claims the benefit of U.S. Provisional Application No. 63/517,365, filed on Aug. 3, 2023, which applications are hereby incorporated herein by reference.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged. An example of such packaging systems is Package-on-Package (POP) technology. In a PoP device, a top semiconductor package is stacked on top of a bottom semiconductor package to provide a high level of integration and component density. PoP technology generally enables production of semiconductor devices with enhanced functionalities and small footprints on a printed circuit board (PCB).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of an integrated circuit die in accordance with some embodiments.

FIGS. 2 through 5 illustrate cross-sectional views of intermediate steps during a process for forming a first package component in accordance with some embodiments.

FIGS. 6A, 6B, 7A, 7B, 8, 9, 10, 11A, and 11B illustrate cross-sectional views and top-down views of intermediate steps during a process for forming a semiconductor package in accordance with some embodiments.

FIGS. 12 through 14 illustrate cross-sectional views and top-down views of intermediate steps during a process for forming a semiconductor package in accordance with some embodiments.

FIGS. 15 and 16 illustrate cross-sectional views and top-down views of intermediate steps during a process for forming a semiconductor package in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In accordance with some embodiments, a first package component is bonded to a second package component by a plurality of functional connectors. In some embodiments, the plurality of functional connectors are solder connectors although other types of connections can be used as well. A plurality of spacer connectors is disposed between the first and second package components during the bonding process to space the first package component and second package component apart from each other at a desired distance. For example, each of the plurality of spacer connectors has a larger diameter than a height of each of the plurality of function connectors, and the spacer connectors can ensure that a desired minimum standoff height is maintained between the first and second package components during the bonding process. The minimum standoff height may correspond to a height where the functional connectors can be reflowed without bridging adjacent function connectors together. As a result, the plurality of spacer connectors provides improved bump standoff height uniformity control between the first and second package components during bonding. In various embodiments, the plurality of spacer connectors improves standoff height control during bonding, thereby reducing manufacturing defects (e.g., solder bridging) and improving yield.

Various embodiments are described below in a particular context. Specifically, a chip on wafer on substrate (CoWoS™) package is described. However, various embodiments may also be applied to other types of packaging technologies, such as, integrated fan-out (InFO) packages, silicon chip bonding, or the like.

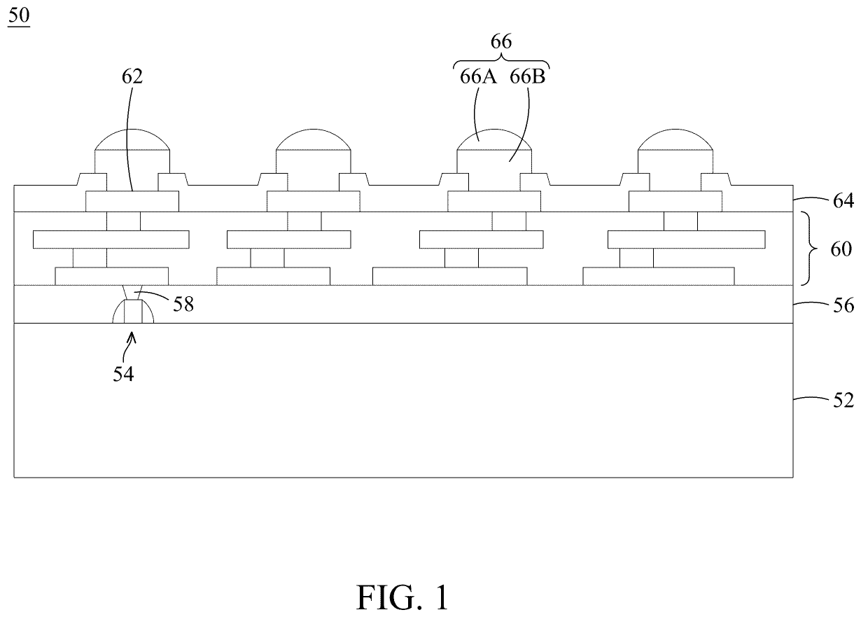

FIGS. 1 through 11B illustrate various intermediary steps of forming a semiconductor package according to various embodiments. FIG. 1 illustrates a cross-sectional view of an integrated circuit die 50 in accordance with some embodiments. The integrated circuit die 50 will be packaged in subsequent processing to form an integrated circuit package. The integrated circuit die 50 may be a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), the like, or combinations thereof.

The integrated circuit die 50 may be formed in a wafer, which may include different device regions that are singulated in subsequent steps to form a plurality of integrated circuit dies. The integrated circuit die 50 may be processed according to applicable manufacturing processes to form integrated circuits. For example, the integrated circuit die 50 includes a semiconductor substrate 52, such as silicon, doped or undoped, or an active layer of a semiconductor-on-insulator (SOI) substrate. The semiconductor substrate 52 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The semiconductor substrate 52 has an active surface (e.g., the surface facing upwards in FIG. 1), sometimes called a front side, and an inactive surface (e.g., the surface facing downwards in FIG. 1), sometimes called a back side.

Devices (represented by a transistor) 54 may be formed at the front surface of the semiconductor substrate 52. The devices 54 may be active devices (e.g., transistors, diodes, etc.), capacitors, resistors, etc. An inter-layer dielectric (ILD) 56 is over the front surface of the semiconductor substrate 52. The ILD 56 surrounds and may cover the devices 54. The ILD 56 may include one or more dielectric layers formed of materials such as Phospho-Silicate Glass (PSG), Boro-Silicate Glass (BSG), Boron-Doped Phospho-Silicate Glass (BPSG), undoped Silicate Glass (USG), or the like.

Conductive plugs 58 extend through the ILD 56 to electrically and physically couple the devices 54. For example, when the devices 54 are transistors, the conductive plugs 58 may couple the gates and source/drain regions of the transistors. The conductive plugs 58 may be formed of tungsten, cobalt, nickel, copper, silver, gold, aluminum, the like, or combinations thereof. An interconnect structure 60 is over the ILD 56 and conductive plugs 58. The interconnect structure 60 interconnects the devices 54 to form an integrated circuit. The interconnect structure 60 includes, for example, metallization patterns in dielectric layers on the ILD 56. The metallization patterns include metal lines and vias formed in one or more low-k dielectric layers with damascene processes, for example. The metallization patterns of the interconnect structure 60 are electrically coupled to the devices 54 by the conductive plugs 58.

The integrated circuit die 50 further includes pads 62, such as aluminum pads, to which external connections are made. The pads 62 are on the active side of the integrated circuit die 50, such as in and/or on the interconnect structure 60. One or more passivation films 64 are on the integrated circuit die 50, such as on portions of the interconnect structure 60 and pads 62. Openings extend through the passivation films 64 to the pads 62.

Die connectors 66 extend through the openings in the passivation films 64 and are physically and electrically coupled to respective ones of the pads 62. In some embodiments, the die connectors 66 are microbumps or the like and may include comprise under bump metallization (UBMs) 66A with solder regions 66B disposed thereon. In other embodiments, the solder regions 66B may be omitted from the die connectors 66. The die connectors 66 may be formed by, for example, plating, stenciling, combinations thereof, or the like.

In some embodiments, the integrated circuit die 50 is part of die stack that includes multiple semiconductor substrates 52. For example, the die stack may be a memory device such as a hybrid memory cube (HMC) module, a high bandwidth memory (HBM) module, or the like that includes multiple memory dies. In such embodiments, the die stack includes multiple integrated circuit die 50 interconnected by through-substrate vias (TSVs), which extend through the substrates 52 of the integrated circuit dies 50. Each of the semiconductor substrates 52 may (or may not) have an interconnect structure 60.

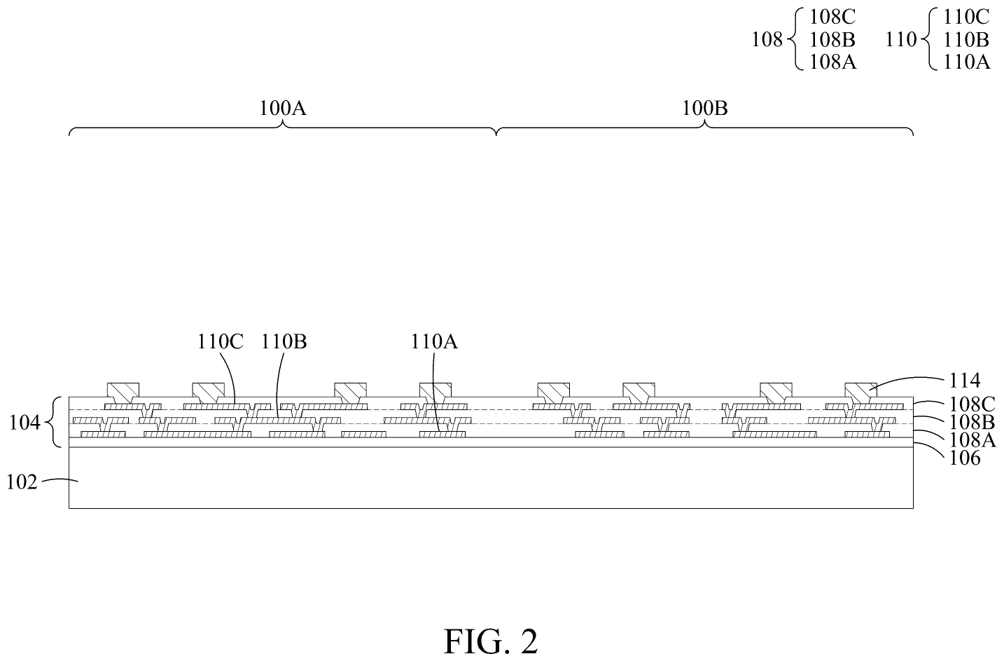

FIGS. 2 through 5 illustrate cross-sectional views of intermediate steps during a process for forming a first package component 100, in accordance with some embodiments. Referring first to FIG. 2, a carrier substrate 102 is provided. The carrier substrate 102 may be a glass carrier substrate, a ceramic carrier substrate, or the like. The carrier substrate 102 may be a wafer, such that multiple packages can be formed on the carrier substrate 102 simultaneously. For example, a first package region 100A and a second package region 100B are illustrated, and one or more of the integrated circuit dies 50 are packaged to form an integrated circuit package (e.g., the first package component 100) in each of the package regions 100A and 100B. The carrier substrate 102 may be a bulk material that is free of any active or passive devices, for example.

A redistribution structure 104 may be formed on the carrier substrate 102. In the embodiment shown, the redistribution structure 104 includes a dielectric layer 106, dielectric layers 108 (labeled 108A, 108B, and 108C), and metallization patterns 110 (sometimes referred to as redistribution layers or redistribution lines, labeled 110A, 110B, and 110C).

The dielectric layer 106 may be formed on the carrier substrate 102. The bottom surface of the dielectric layer 106 may be in contact with the top surface of the carrier substrate 102. In some embodiments, the dielectric layer 106 is formed of a polymer, such as polybenzoxazole (PBO), polyimide, benzocyclobutene (BCB), or the like. In other embodiments, the dielectric layer 106 is formed of a nitride such as silicon nitride; an oxide such as silicon oxide, phosphosilicate glass (PSG), borosilicate glass (BSG), boron-doped phosphosilicate glass (BPSG), or the like; or the like. The dielectric layer 106 may be formed by any acceptable deposition process, such as spin coating, CVD, laminating, the like, or a combination thereof. In some embodiments, the dielectric layer 106 may be free of any metallization patterns and protect overlying metallization patterns 110 from damage when the carrier substrate 102 is subsequently removed. As such, the dielectric layer 106 may also be referred to as a buffer layer or protective layer.

The metallization pattern 110A may be formed on the dielectric layer 106. As an example to form metallization pattern 110A, a seed layer is formed over the dielectric layer 106. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, physical vapor deposition (PVD) or the like. A photoresist (not shown) is then formed and patterned on the seed layer. The photoresist may be formed by spin coating or the like and may be exposed to light for patterning. The pattern of the photoresist corresponds to the metallization pattern 110A. The patterning forms openings through the photoresist to expose the seed layer. A conductive material is formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching. The remaining portions of the seed layer and conductive material form the metallization pattern 110A.

The dielectric layer 108A may be formed on the metallization pattern 110A and the dielectric layer 106. In some embodiments, the dielectric layer 108A is formed of a polymer, which may be a photo-sensitive material such as PBO, polyimide, BCB, or the like, that may be patterned using a lithography mask. In other embodiments, the dielectric layer 108A is formed of a nitride such as silicon nitride; an oxide such as silicon oxide, PSG, BSG, BPSG; or the like. The dielectric layer 108A may be formed by spin coating, lamination, CVD, the like, or a combination thereof. The dielectric layer 108A is then patterned to form openings exposing portions of the metallization pattern 110A. The patterning may be formed by an acceptable process, such as by exposing the dielectric layer 108A to light when the dielectric layer 108A is a photo-sensitive material or by etching using, for example, an anisotropic etch. If the dielectric layer 108A is a photo-sensitive material, the dielectric layer 108A can be developed after the exposure.

Alternatively, in other embodiments that are not specifically illustrated, the dielectric layer 108A may be deposited prior to forming the metallization pattern 110A. For example, the dielectric layer 108A may be deposited of a similar material using a similar process as described above. After deposition, a damascene process (e.g., a dual damascene process or a single damascene process) may be used to pattern openings in the dielectric layer 108A. The patterning of the openings may correspond to a pattern of the metallization pattern 110A. The metallization pattern 110A may then be deposited in the openings, e.g., using a plating process. The metallization pattern 110A may initially overflow the openings, and a planarization process (e.g., a CMP process or the like) may be used to level top the dielectric layer 108A and the metallization pattern 110A.

Additional metallization patterns 110B and 110C may be formed over the metallization pattern 110A in dielectric layers 108B and 108C, respectively. Specifically, the metallization patterns 110B are formed in dielectric layers 108B, which is disposed over the dielectric layer 108A and the metallization patterns 110A. Further, the metallization patterns 110C are formed in dielectric layers 108C, which is disposed over the dielectric layer 108B and the metallization patterns 110B. Each of the dielectric layers 108B and 108C may by formed of a similar material and using similar processes as described above with respect to the dielectric layer 108A. Further, each of the metallization patterns 110B and 110C may be formed of a similar material and using similar processes as described above with respect to the metallization pattern 110A.

FIG. 2 illustrates a redistribution structure 104 having a specific number of metallization patterns (e.g., the metallization patterns 110A, 110B, and 110C) for illustrative purposes. In some embodiments, the back-side redistribution structure 104 may include any number of dielectric layers and metallization patterns. If more dielectric layers and metallization patterns are to be formed, steps and processes discussed above may be repeated. The metallization patterns may include one or more conductive elements. The conductive elements may be formed during the formation of the metallization pattern by forming the seed layer and conductive material of the metallization pattern over a surface of the underlying dielectric layer and in the opening of the underlying dielectric layer, thereby interconnecting and electrically coupling various conductive lines. Further, the completed redistribution structure 104 may be free of any active devices and/or free of any passive devices, and the carrier substrate 102 and the redistribution structure 104 may be collectively referred to as an interposer.

As further illustrated by FIG. 2, UBMs 114 of the redistribution structure 104 are formed over the metallization pattern 110C and the dielectric layer 108C. The UBMs 114 are formed for external connection to the redistribution structure 104. The UBMs 114 have landing pad portions on and extending along the major surface of the dielectric layer 108C, and have via portions extending through the dielectric layer 108C to physically and electrically couple the metallization pattern 110C. As a result, the UBMs 114 are electrically coupled to the metallization patterns of the redistribution structure 104. The UBMs 114 formed of a similar material and using similar processes as described above with respect to the metallization pattern 110A. In some embodiments, the UBMs 114 have a different size (e.g., a different thickness) than the metallization patterns 110A, 110B, and 110C.

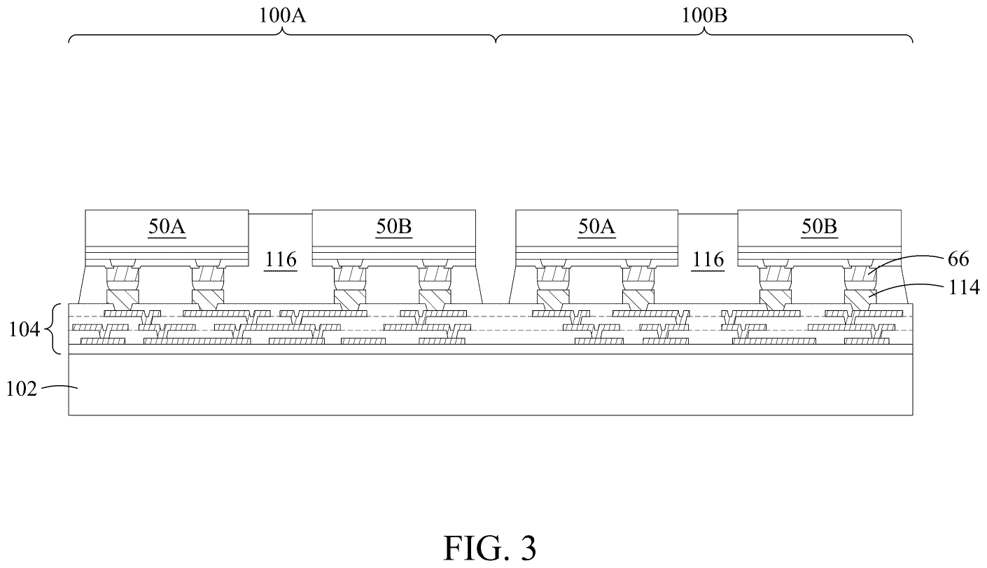

In FIG. 3, integrated circuit dies 50 (e.g., a first integrated circuit die 50A and a second integrated circuit die 50B) are bonded to the redistribution structure 104 in each of the package regions 100A/100B. The integrated circuit dies 50 may be flip-chip bonded to the redistribution structure 104 by bonding die connectors 66 to the UBMs 114, for example. Alternatively, the integrated circuit dies 50 may be bonded to the redistribution structure 104 using a different bonding mechanism, such as other solder bonding processes (e.g., thermal compression bonding processes) or solder-less bonding processes (e.g., with direct dielectric-to-dielectric and metal-to-metal bonding).

The first integrated circuit die 50A and the second integrated circuit die 50B may be formed in processes of a same technology node, or may be formed in processes of different technology nodes. For example, the first integrated circuit die 50A may be of a more advanced process node than the second integrated circuit die 50B. The integrated circuit dies 50A and 50B may have different sizes (e.g., different heights and/or surface areas), or may have the same size (e.g., same heights and/or surface areas). Other combinations of integrated circuit dies (e.g., with or without stacked dies) are also possible in other embodiments.

An underfill 116 may be formed between the integrated circuit dies 50 and the redistribution structure 104 in each of the package regions 100A/100B. Optionally, the underfill 116 may further extend along sidewalls of the integrated circuit dies 50 to partially encapsulant the integrated circuit dies 50. For example, the underfill 116 may partially fill a gap between the first integrated circuit die 50A and the second integrated circuit die 50B in each of the package regions 100A/100B. The underfill 116 may reduce stress and protect the joints resulting from reflowing the die connectors 66. In some embodiments, an underfill 116 may be formed by a capillary flow process after the dies 50 are attached to the redistribution structure 104 or may be formed by a suitable deposition method before the dies 50 are attached to the redistribution structure 104.

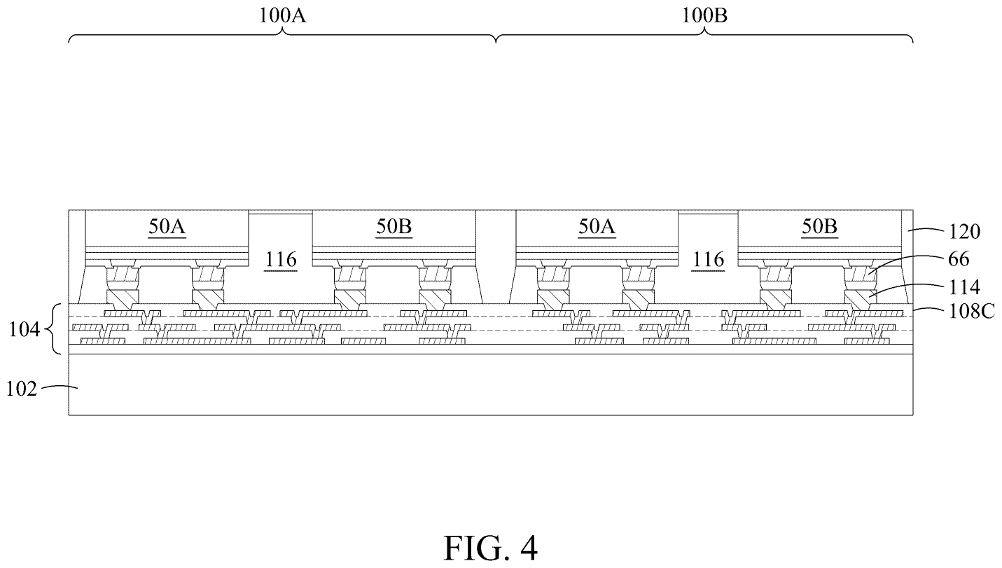

In FIG. 4, an encapsulant 120 is formed on and around the various components. After formation, the encapsulant 120 encapsulates the integrated circuit dies 50, and the encapsulant 120 may contact a top surface of redistribution structure 104 (e.g., a top surface of the dielectric layer 108C). The encapsulant 120 may be a molding compound, epoxy, or the like. The encapsulant 120 may be applied by compression molding, transfer molding, or the like, and may be formed over the redistribution structure 104 such that the integrated circuit dies 50 are buried or covered. In some embodiments, the encapsulant 120 is further formed in any remaining gap regions between the integrated circuit dies 50, such as any regions not filled by the underfill 116. The encapsulant 120 may be applied in liquid or semi-liquid form and then subsequently cured.

After the encapsulant 120 is formed, a planarization process is performed on the encapsulant 120 to one or more of the integrated circuit dies 50 (e.g., the stacked integrated circuit dies 50C). The planarization process may also remove material of the integrated circuit dies 50 that are exposed while other ones of the integrated circuit dies (e.g., the integrated circuit dies 50A and 50B) may remain buried in the encapsulant 120 after planarization. A top surface of the encapsulant 120 are substantially coplanar after the planarization process within process variations. The planarization process may be, for example, a chemical-mechanical polish (CMP), a grinding process, or the like. In some embodiments, the planarization may be omitted.

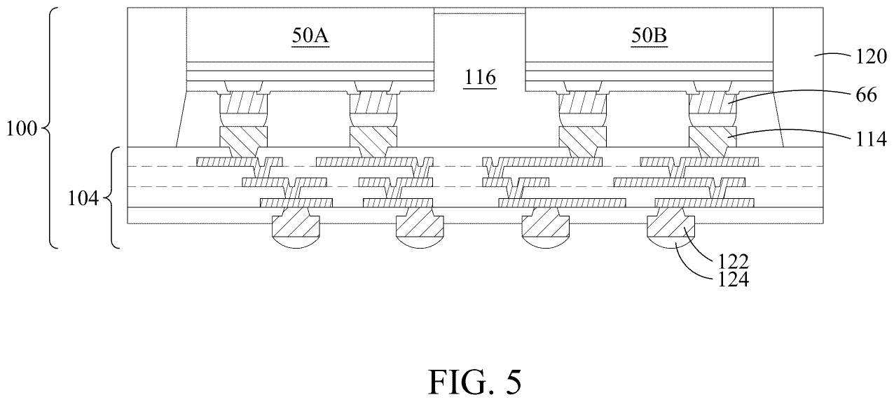

In FIG. 5, the substrate 102 is removed to expose the dielectric layer 106 of the redistribution structure 104. Removing the substrate 102 may be performed using any suitable process, such as a grinding process, a CMP process, an etch back process, combinations thereof or the like. Under bump metallizations (UBMs) 122 are formed for external connection to the redistribution structure 104. The UBMs 122 have bump portions on and extending along the major surface of the dielectric layer 106, and have via portions extending through the dielectric layer 106 to physically and electrically couple the metallization pattern 110A. As a result, the UBMs 122 are electrically coupled to the integrated circuit dies 50.

As an example of forming the UBMs 122, openings are formed through the dielectric layer 106 to expose portions of the metallization pattern 110A. The openings may be formed, for example, using laser drilling, etching, or the like. The conductive UBMs 122 are formed in the openings. In some embodiments, the UBMs 122 comprise flux and are formed in a flux dipping process. In some embodiments, a conductive paste 124 is disposed on the UBMs 122. The conductive paste 124 may be a solder paste, silver paste, or the like, and are dispensed in a printing process, for example. In some embodiments, the UBMs 122 are formed in a manner similar to the metallization pattern 110A, and may be formed of a similar material as the metallization pattern 110A. In some embodiments, the UBMs 122 have a different size than the metallization patterns 110A, 110B, and 110C. For example, the UBMs 122 may be thicker than the metallization patterns 110A, 110B, and/or 110C.

A singulation process is then performed by sawing along scribe line regions, e.g., between the first package region 100A and the second package region 100B. The sawing singulates the first package region 100A from the second package region 100B. The resulting, singulated, first package component 100 is from one of the first package region 100A or the second package region 100B.

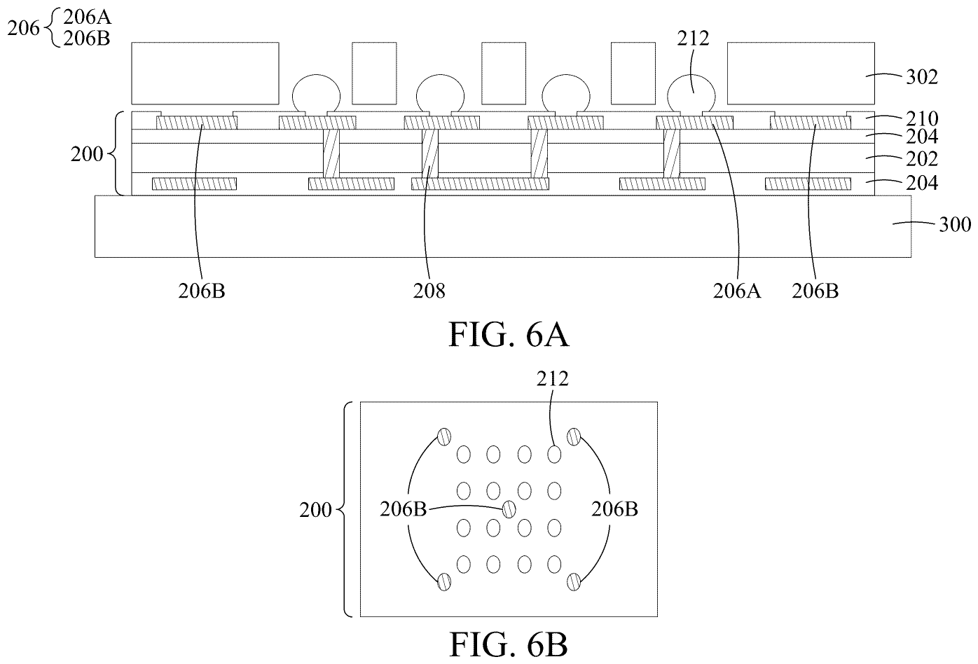

FIGS. 6A, 6B, 7A, 7B, and 8 illustrate intermediate steps of forming connectors (including functional connectors and spacer connectors) on a package component according to some embodiments. FIGS. 6A and 6B illustrate a package substrate 200 on a chuck 300. Although a package substrate 200 is illustrated, various embodiments may be applied to other types of package components, such as interposers, or the like. FIG. 6A illustrates a cross-sectional view of the package substrate 200 while FIG. 6B shows a plan view of the package substrate 200.

In some embodiments, the chuck 300 is a vacuum chuck that maintains a position of the package substrate 200 while the connectors are formed on the package substrate 200. The package substrate 200 includes a substrate core 202 and one or more routing layers 204 on opposing sides of the core 202. The substrate core 202 may be an insulating core such as a fiberglass reinforced resin core. One example core material is fiberglass resin such as FR4. Alternatives for the core material include bismaleimide-triazine (BT) resin, or alternatively, other PCB materials or films. Build up films such as ABF or other laminates may be used for substrate core 202. In other embodiments, the core 202 may be made of a semiconductor material such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations of these, and the like, may also be used. In embodiments where the core 202 is a semiconductor substrate, the core 202 may include active and passive devices (not shown) disposed thereon. A wide variety of devices such as transistors, capacitors, resistors, combinations of these, and the like may be used to generate the structural and functional requirements of the design for the device stack. The devices may be formed using any suitable methods. In other embodiments, the substrate core 202 is substantially free of active and passive devices.

The routing layers 204 may include metallization layers and vias (not shown). In some embodiments, the metallization layers may be formed over the active and passive devices (if present) and are designed to connect the various devices to form functional circuitry. The metallization layers may be formed of alternating layers of dielectric material (e.g., low-k dielectric material, a polymer material, or the like) and conductive material (e.g., copper) with vias interconnecting the layers of conductive material and may be formed through any suitable process (such as plating, damascene, dual damascene, or the like). In embodiments where the routing layers 204 are disposed on opposing surfaces of the core 202, through vias 208 may be formed to extend through the core to electrically connect the metallization patterns of the opposing routing layers 204 together. The through vias 208 may be formed by patterning openings (e.g., by drilling) through the core 202 and/or portions of the routing layers 204, and plating at least sidewalls of the openings with a conductive material (e.g., copper). Alternatively, the routing layers 204 may only be formed on the top side of the core 202, with the routing layers 204 between the core 202 and the chuck 300 being omitted. In such embodiments, the through vias 208 may provide connection from the routing layers 204 to a backside if the core 202, such as to bond pads on the backside of the core 202.

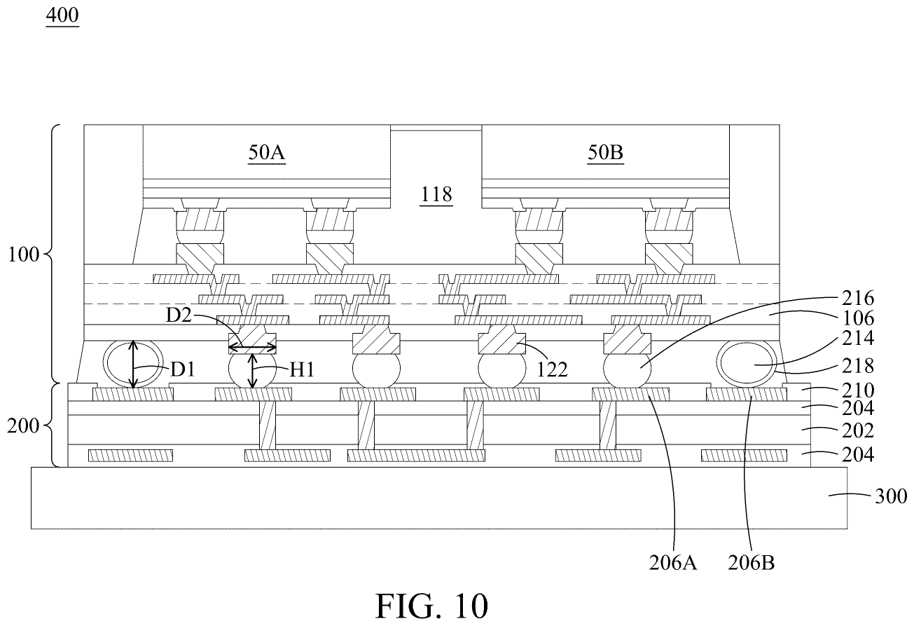

The routing layers 204 may further include with the bond pads 206 (including functional bond pads 206A and dummy bond pads 206B) at an exterior surface of the routing layers 204. The functional bond pads 206A may be physically and electrically coupled to the metallization layers and vias, allowing for electrical connection to other package components (e.g., the package component 100, see FIG. 10). The dummy bond pads 206B may be electrically isolated from the metallization layers and vias of the routing layers 204. Thus, the dummy bond pads 206B may not provide any electrical functionality in the package substrate 200. An insulating layer 210 may be formed over the substrate core 202, such as over the routing layers 204 that opposite the chuck 300. In some embodiments, the insulating layer 210 is a solder resist, a polymer layer, or the like. Openings are formed in the insulating layer 210 (e.g., by a lithography process) to expose the bond pads 206 of the routing layers 204. The insulating layer 210 may be used to protect areas of the core 202 from external damage.

As further illustrated by FIGS. 6A and 6B, functional connectors 212 are placed on the functional bond pads 206A. For example, the functional connectors 212 may be placed in the openings in the insulating layer 210 to contact the functional bond pads 206A. The functional connectors 212 may be solder connectors, such as solder balls or other conductive connectors may be used in other embodiments. The functional connectors 212 may be placed in a printing process with a stencil 302, for example. During the printing process, the stencil 302 may cover the dummy bond pads 206B such that the functional connectors 212 are not placed on the dummy bond pads 206B. The functional connectors 212 may allow the package substrate 200 to be attached and electrically connected to another component, such as, the first package component 100 (see FIG. 10). As illustrated by the top-down view of FIG. 6B, the functional connectors 212 may be placed on the package substrate 200 in a grid array of rows and columns.

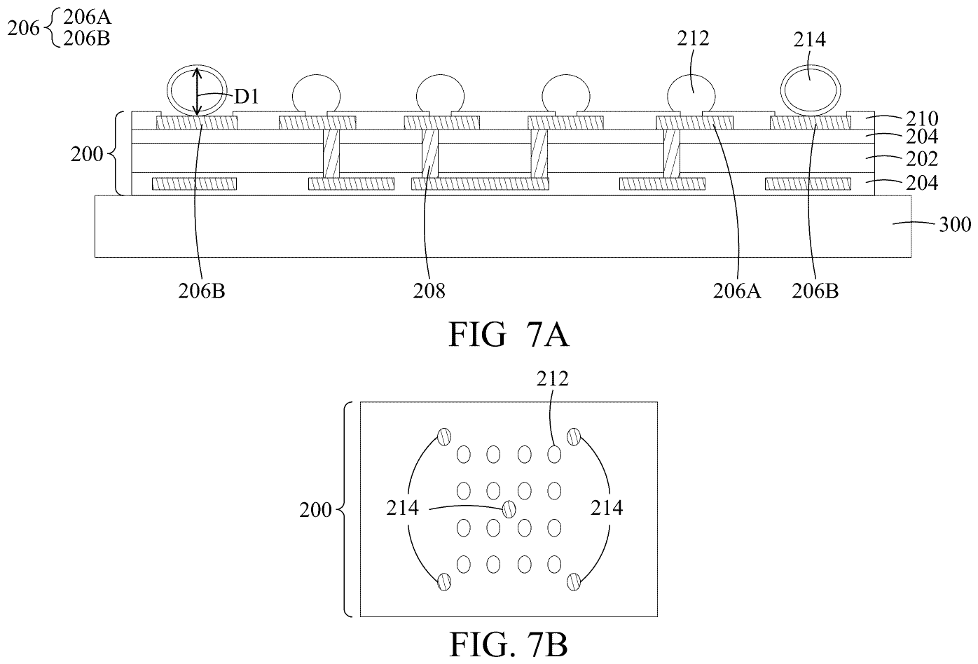

In FIGS. 7A and 7B, spacer connectors 214 are placed on the dummy bond pads 206B. FIG. 7A illustrates a cross-sectional view of the package 200 with the spacer connectors 214 while FIG. 7B illustrates a top-down view of the package 200 with the spacer connectors 214. In some embodiments, the spacer connectors 214 may be placed in openings in the insulating layer 210 and contact the dummy bond pads 206B. The spacer connectors 214 may be individually placed on the dummy bond pads 206B with a ball mount repair tool, for example. The spacer connectors 214 may comprise a copper-cored ball, a plastic ball, a rubber ball, or the like. In some embodiments, an exterior of the spacer connectors 214 may be plated with solder to allow the spacer connectors 214 to be affixed to the dummy connectors 214 with a reflow process.

In some embodiments, the spacer connectors 214 are larger than the functional connectors 212. For example, the spacer connectors 214 may extend higher than the functional connectors 212 for improved standoff height control in subsequent bonding processes (see FIG. 10). In some embodiments, a diameter D1 of the spacer connectors 214 may be in a range of 40 μm to 150 μm. It has been observed that when the diameter D1 of the spacer connectors 214 is in the above range, standoff height control is improved during the subsequent bonding, and manufacturing defects (e.g., solder bridging between adjacent functional connectors 212) can be advantageously reduced. As illustrated by the plan view of FIG. 7B, the spacer connectors 214 may be positioned at various locations to facilitate standoff height control in subsequent bonding steps. For example, the spacer connectors 214 may be distributed at various locations so that it can support another package component over the package substrate 200 with sufficient stability during bonding. In some embodiments, the spacer connectors 214 may be disposed at corners of the package substrate 200 in a plan view. Further, at least one of the spacer connectors 214 may be disposed at a center of the package substrate 200 in a plan view for improved stability.

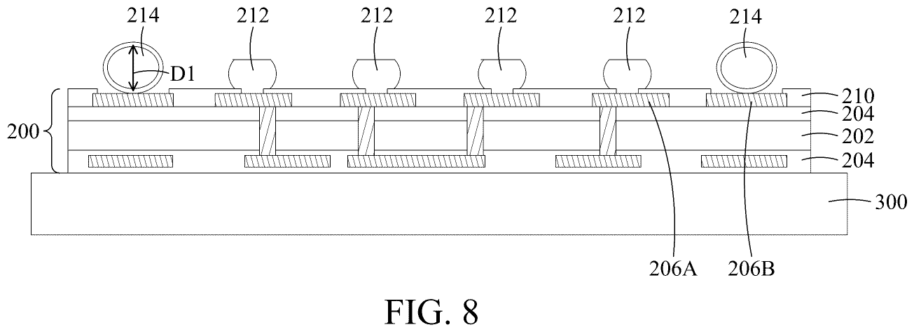

After the spacer connectors 214 and the functional connectors 212 are placed on the bond pads 206, a reflow process may be performed to adhere the functional connectors 212 and the spacer connectors 214 to the functional bond pads 206A and the dummy bond pads 206B, respectively. The resulting structure is illustrated by FIG. 8. The reflow process may be performed at a temperature in a range of 50° C. to 150° C. in some embodiments. In other embodiments, the reflow process may be performed at a different temperature range. During the reflow process, a coin head (not illustrated) may be pressed on the functional connectors 212 to flatten a top surface of the functional connectors 212 and reduce a height of the functional connectors 212. The flattening process may also be referred to as a “bump coin” process. Flatting the functional connectors 212 may facilitate bonding to connectors of other package components. Further, reducing a height of the functional connectors 212 may allow the spacer connectors 214 to have a suitable height for standoff height control during the subsequent bonding processes. In some embodiments, the spacer connectors 214 may have a same height as the functional connectors 212 prior to the flattening process, and the spacer connectors 214 may extend higher than the functional connectors 212 after the flattening process.

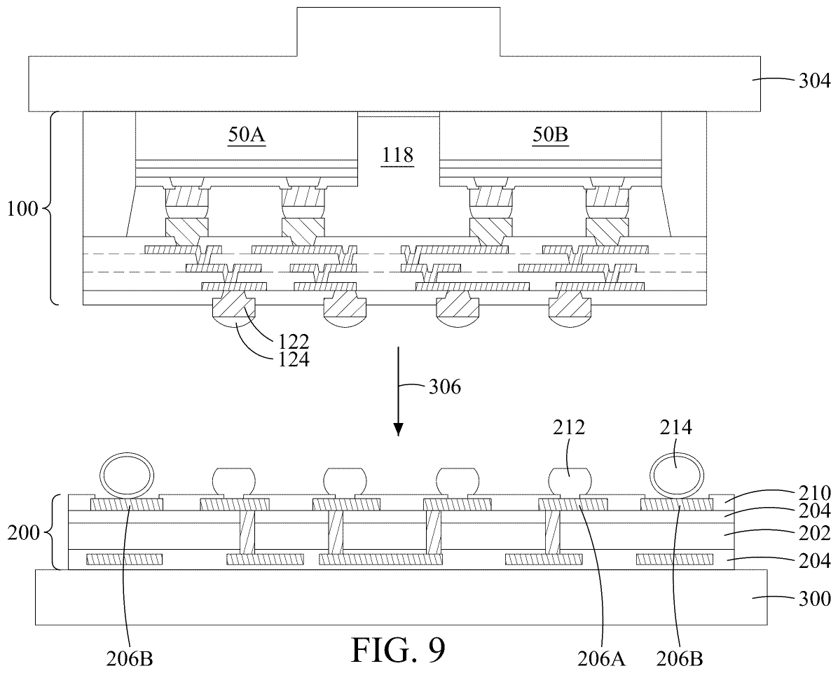

In FIG. 9, the first package component 100 and the package substrate 200 are aligned. For example, the first package component 100 may be placed over the package substrate 200 by a bond head 304. The bond head 304 holds and maneuvers the first package component during the bonding process. Aligning the first package component 100 to the package substrate 200 may include aligning the UBMs 122 of the first package component 100 to overlap the functional connectors 212 of the package substrate 200. The bond head 304 may then lower the first package component 100 to contact the functional connectors 212 as indicated by arrow 306.

In FIG. 10, a bonding process is performed. The bonding process may be a TCB process, a flip chip bonding process, or the like. In some embodiments, the bonding process includes reflowing the functional connectors 212 and the conductive paste 124 (if present) to attach the first package component 100 to the functional bond pads 206A. The functional connectors 212 and the conductive paste 124 may fuse together, thereby forming functional connectors 216 that electrically connect the circuitry of the first package component 100 to the circuitry of the package substrate 200. In this manner, the first package component 100 may be electrically connected to the package substrate 200 through the UBMs 122, the functional connectors 216, and the functional bond pads 206A.

During the bonding process, the spacer connectors 214 may maintain a desired standoff height between the first package component 100 and the package substrate 200. For example, the spacer connectors 214 may extend between and contact surfaces of the first package component 100 and the package substrate 200 during bonding to physically space the first package component 100 apart from the package substrate 200. The standoff height may refer to a vertical distance between exterior, insulating surfaces of the first package component 100 and the package substrate 200, such as a vertical distance between the dielectric layer 106 and the insulating layer 210. When the standoff height between the first package component 100 and the package substrate 200 becomes unacceptably small, the functional connectors 216 may spread excessively in a lateral direction during reflow, and adjacent functional connectors 216 may bridge together causing shorts. The spacer connectors 214 are positioned at various locations to act as a physical barrier and maintain a desired standoff height between the first package component 100 and the package substrate 200 throughout the bonding process to prevent such bridging defects. For example, a diameter D1 of the spacer connectors 214 may be greater than a diameter D2 of the UBM 122 and also greater than a height H1 of the functional connectors 216. In various embodiments, the spacer connectors 214 have a sufficiently small diameter to allow the first package component 100 and the package substrate 200 to bond together while also having a sufficiently large diameter to maintain a desired standoff height to reduce defects. For example, in embodiments where the diameter D2 of the UBMs 122 is in a range of 30 μm to 100 μm and a height of the functional connectors 216 is in a range of 20 μm to 100 μm, the diameter D1 of the spacer connectors 214 may be in a range of 40 μm to 150 μm. It has been observed that when the UBMs 122, the functional connectors 216, and the spacer connectors 214 have the above dimensions, the first package component 100 and the package substrate 200 can be bonded together with reduced defects (e.g., bridging defects) and improved yield.

As also illustrated by FIG. 10, an underfill 218 may be formed between the first package component 100 and the package substrate 200 and surrounding the functional connectors 216 and the spacer connectors 214. The underfill 218 may optionally extend into the openings in the insulating layer 210 to contact top surfaces of the functional bond pads 206A and/or the dummy bond pads 206B. The underfill 218 may be formed by a capillary flow process after the first package component 100 is attached or may be formed by a suitable deposition method before the first package component 100 is attached. Thus, a package 400 is formed comprising the first package component 100 and the package substrate 200.

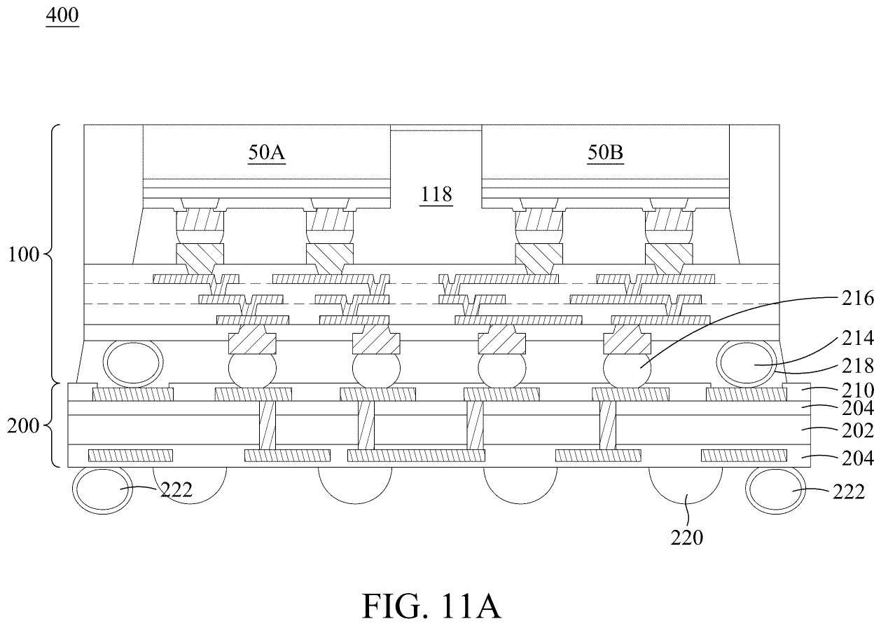

In FIGS. 11A and 11B, the package 400 (including the bonded first package component 100 and the package substrate 200) may be removed from the chuck 300. After the package 400 is removed, and connectors are formed on a surface of the package substrate 200 that is opposite to the first package component 100. In some embodiments, the connectors may include functional connectors 220 and spacer connectors 222 as illustrated by FIG. 11A. In other embodiments, the spacer connectors 222 are omitted and only functional connectors 220 are disposed on the surface of the package substrate 200 opposite to the first package component 100. The functional connectors 220 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The functional connectors 220 may include a conductive material such as solder, copper, aluminum, gold, nickel, silver, palladium, tin, the like, or a combination thereof. In some embodiments, the functional connectors 220 are formed by initially forming a layer of solder through evaporation, electroplating, printing, solder transfer, ball placement, or the like. Once a layer of solder has been formed on the structure, a reflow may be performed in order to shape the material into desired bump shapes. In another embodiment, the functional connectors 220 comprise metal pillars (such as copper pillars) formed by sputtering, printing, electro plating, electroless plating, CVD, or the like. The metal pillars may be solder-free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

The functional connectors 220 may be electrically connected to metallization patterns of the package substrate 200, and the conductive connectors 220 may be used to connect the package substrate 200 to another package component (not explicitly illustrated), such as a printed circuit board (PCB), motherboard, or the like. The spacer connectors 222 may be made of a similar material and using similar processes as the spacer connectors 214. The spacer connectors 222 may be used to maintain a suitable standoff height between the package substrate 200 and the other package component in a similar manner as the spacer connectors 214 described above. In some embodiments, the spacer connectors 222 may extend farther from the package substrate 200 as the functional connectors 220 for improved standoff height control.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

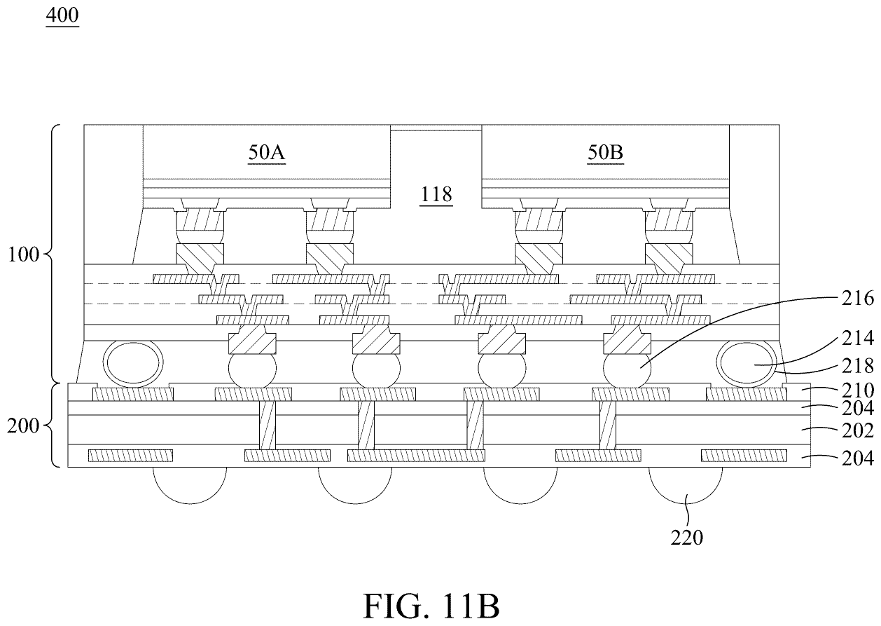

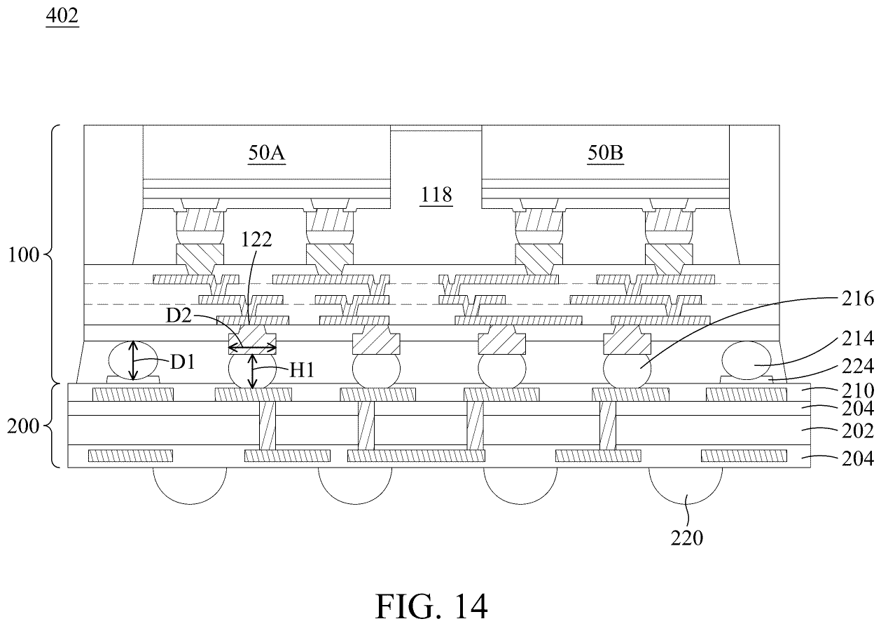

In the above embodiments, the spacer connectors 214 are attached to the package substrate 200 by reflowing a solder layer of the spacer connectors 214, thereby attaching the spacer connectors 214 to dummy bond pads 206B of the package substrate 200. In other embodiments, the spacer connectors 214 may be attached to the package substrate 200 in a different manner. For example, FIGS. 12 through 14 illustrate an alternate embodiment where a package 402 is formed (see FIG. 14). In FIGS. 12 through 14, like reference numerals indicate like elements formed by like processes as described above with respect to the package 400 unless otherwise noted.

In FIG. 12, functional connectors 212 are disposed on functional bond pads 206A through openings in the insulating layer 210 in a similar manner as described above with respect to FIGS. 6A and 6B. Further, spacer connectors 214 are attached to a top surface of the insulating layer 210 by an adhesive layer 224 (e.g., an epoxy glue). The spacer connectors 214 may be made of a different material than the functional connectors 212. For example, the spacer connectors 214 may comprise a rubber ball, a copper-cored ball, a plastic ball, or the like. The spacer connectors 214 may or may not be solder plated. The spacer connectors 214 may be disposed on a top surface of the insulating layer 210 to overlap dummy bond pads 206B without being disposed in any openings of the insulating layer 210. For example, the insulating layer 210 may cover a bottom surface of the spacer connectors 214 and physically separate the spacer connectors 214 from the dummy bond pads 206B. In some embodiments, the dummy bond pads 206B may be omitted entirely. In a plan view, the spacer connectors 214 may be disposed at corner regions and a center of the package substrate (see FIG. 7B).

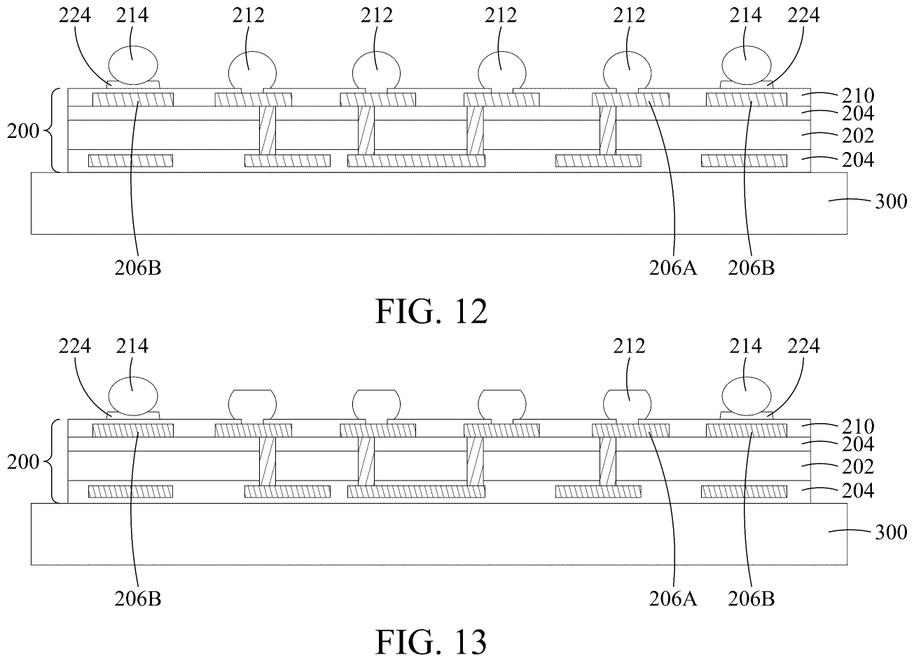

FIGS. 13 and 14 illustrate additional processing steps to form the package 402. In FIG. 13, a reflow process is performed to attach the functional connectors 212 to the functional bond pads 206A. A flattening process may be performed during the reflow process in a similar manner as described above with respect to FIG. 8. In FIG. 14, the first package component is bonded to the package substrate 200 using a similar process as described above in FIGS. 10, 11A, and 11B. During the bonding process, the spacer connectors 214 may be used to maintain a suitable standoff height between the first package component 100 and the package substrate 200. In various embodiments, the spacer connectors 214 have a sufficiently small diameter to allow the first package component 100 and the package substrate 200 to bond together while also having a sufficiently large diameter to maintain a desired standoff height to reduce defects. For example, in embodiments where the diameter D2 of the UBMs 122 is in a range of 30 μm to 100 μm and a height of the functional connectors 216 is in a range of 20 μm to 100 μm, the diameter D1 of the spacer connectors 214 may be in a range of 40 μm to 150 μm. It has been observed that when the UBMs 122, the functional connectors 216, and the spacer connectors 214 have the above dimensions, the first package component 100 and the package substrate 200 can be bonded together with reduced defects (e.g., bridging defects) and improved yield. Functional connectors 220 and spacer connectors (not illustrated) may then be formed on a surface of the package substrate opposite to the first package component 100.

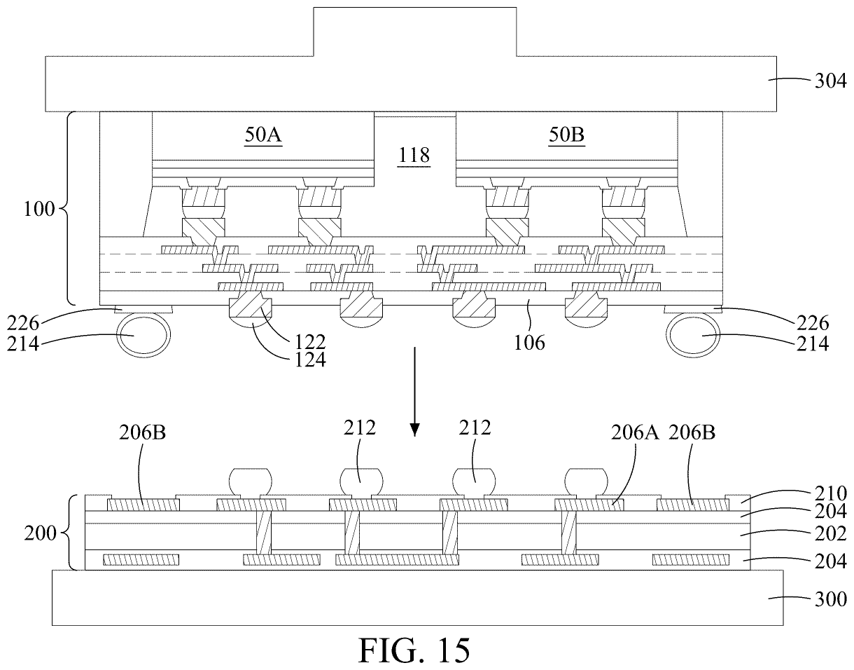

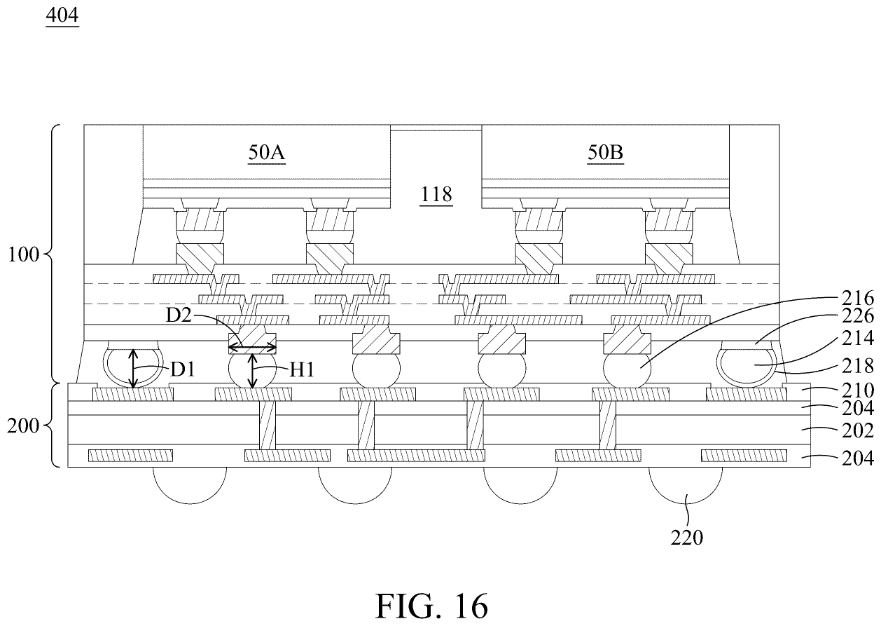

In the above embodiments, the spacer connectors 214 are attached to the package substrate 200 prior to bonding the first package component 100. In other embodiments, the spacer connectors 214 may be attached to first package component 100 and then bonded to the package substrate 200. For example, FIGS. 15 and 16 illustrate an alternate embodiment where a package 404 is formed (see FIG. 16). In FIGS. 15 and 16, like reference numerals indicate like elements formed by like processes as described above with respect to the package 400 unless otherwise noted.

In FIG. 15, the spacer connectors 214 are initially attached to an exterior surface of the first package component 100 by an adhesive 226 (e.g., an epoxy glue). The spacer connectors 214 may be attached to a surface from which the UBMs 122 protrude. For example, the spacer connectors 214 may be attached to the dielectric layer 106, and the UBMs may extend through the dielectric layer 106. When the first package component is aligned to the package substrate 200, the spacer connectors 214 may be aligned to the dummy bond pads 206B. For example, the spacer connectors 214 may overlap openings in the insulating layer 210 that expose the dummy bond pads 206B. The spacer connectors 214 may comprise a rubber ball, a copper-cored ball, a plastic ball, or the like. The spacer connectors 214 may or may not be solder plated.

In FIG. 16, the first package component is bonded to the package substrate 200 using a similar process as described above in FIGS. 10, 11A, and 11B. During the bonding process, the spacer connectors 214 may be used to maintain a suitable standoff height between the first package component 100 and the package substrate 200. Further, the bonding process may include a reflow process that reflows a solder plating on the spacer connectors 214 to bond the spacer connectors 214 to the dummy bond pads 206B. After bonding, the spacer connectors 214 may be disposed at corners and at a center of the package substrate 200 in a plan view (see FIG. 7B).

In various embodiments, the spacer connectors 214 have a sufficiently small diameter to allow the first package component 100 and the package substrate 200 to bond together while also having a sufficiently large diameter to maintain a desired standoff height to reduce defects. For example, in embodiments where the diameter D2 of the UBMs 122 is in a range of 30 μm to 100 μm and a height of the functional connectors 216 is in a range of 20 μm to 100 μm, the diameter D1 of the spacer connectors 214 may be in a range of 40 μm to 150 μm. It has been observed that when the UBMs 122, the functional connectors 216, and the spacer connectors 214 have the above dimensions, the first package component 100 and the package substrate 200 can be bonded together with reduced defects (e.g., bridging defects) and improved yield. Functional connectors 220 and spacer connectors (not illustrated) may then be formed on a surface of the package substrate opposite to the first package component 100.

In accordance with some embodiments, a first package component is bonded to a second package component by a plurality of functional connectors. In some embodiments, the plurality of functional connectors are solder connectors although other types of connections can be used as well. A plurality of spacer connectors is disposed between the first and second package components during the bonding process to space the first package component and second package component apart from each other at a desired distance. For example, each of the plurality of spacer connectors has a larger diameter than a height of each of the plurality of function connectors, and the spacer connectors can ensure that a desired minimum standoff height is maintained between the first and second package components during the bonding process. The minimum standoff height may correspond to a height where the functional connectors can be reflowed without bridging adjacent function connectors together. As a result, the plurality of spacer connectors provides improved bump standoff height uniformity control between the first and second package components during the bonding process. In various embodiments, the plurality of spacer connectors improves standoff height control during bonding, thereby reducing manufacturing defects (e.g., solder bridging) and improving yield.

In some embodiments, a package includes a first package component; a second package component bonded to the first package component by a first plurality of solder connectors; and a first plurality of spacer connectors extending from the first package component to the second package component. A diameter of a first spacer connector of the first plurality of spacer connectors is larger than a height of a first solder connector of the first plurality of solder connectors, and the first plurality of spacer connectors comprises a different material than the first plurality of solder connectors. In some embodiments, a first spacer connector of the first plurality of spacer connectors is disposed in a corner region of the second package component in a plan view. In some embodiments, a first spacer connector of the first plurality of spacer connectors is disposed at a center point of the second package component in a plan view. In some embodiments, the second package component comprises an insulating layer, and the first plurality of solder connectors and the first plurality of spacer connectors each extend through the insulating layer. In some embodiments, the second package component comprises an insulating layer, the first plurality of solder connectors extends through the insulating layer, and the insulating layer covers a bottom surface of the first plurality of spacer connectors. In some embodiments, the first plurality of spacer connectors is adhered to a top surface of the insulating layer by an adhesive. In some embodiments, the diameter of the first spacer connector of the first plurality of spacer connectors is in a range of 40 μm to 150 μm, and the height of the first solder connector of the first plurality of solder connectors is in a range of 30 μm to 100 μm. In some embodiments, each of the first plurality of solder connectors physically contacts a respective conductive pad of a plurality of conductive pads of the first package component, and the diameter of the first spacer connector of the first plurality of spacer connectors is larger than a diameter of a first conductive pad of the plurality of conductive pads in a plan view. In some embodiments, the diameter of the first spacer connector of the first plurality of spacer connectors is in a range of 40 μm to 150 μm, and the diameter of the first conductive pad of the plurality of conductive pads in a plan view is in a range of 20 μm to 100 μm. In some embodiments, each of the first plurality of spacer connectors comprises a rubber ball, a copper-cored ball, or a plastic ball. In some embodiments, each of the first plurality of spacer connectors is solder plated. In some embodiments, the package further includes a second plurality of solder connectors on a surface of the second package component opposite to the first package component; and a second plurality of spacer connectors on the surface of the second package component opposite to the first package component, wherein a diameter of a second spacer connector of the second plurality of spacer connectors is larger than a height of a second solder connector of the second plurality of solder connectors, and wherein the second plurality of spacer connectors comprises a different material than the second plurality of solder connectors.

In some embodiments, a method includes placing a plurality of solder connectors on a first package component; placing a plurality of spacer connectors on the first package component; and performing a first reflow process to adhere the plurality of solder connectors to bond pads of the first package component. A height of the plurality of solder connectors is less than a height of the plurality of spacer connectors after performing the first reflow process. The method further includes bonding a second package component to the first package component. Bonding the second package component to the first package component comprises performing a second reflow process to reflow the plurality of solder connectors while the plurality of spacer connectors physically spaces the second package component apart from the first package component. In some embodiments, performing the first reflow process further adheres the plurality of spacer connectors to the first package component. In some embodiments, the method further includes dispensing an adhesive on the first package component, wherein placing the plurality of spacer connectors on the first package component comprises adhering the plurality of solder connectors to the first package component with the adhesive. In some embodiments, the first package component comprises an insulating layer, the insulating layer comprising: a first plurality of openings, and wherein placing the plurality of solder connectors comprises plurality of the plurality of solder connectors in the first plurality of openings; and a second plurality of openings, and wherein placing the plurality of spacer connectors comprises placing the plurality of the plurality of spacer connectors in the second plurality of openings.

In some embodiments, a package includes a package substrate comprising a solder resist at an exterior surface of the package substrate; a package bonded to the package substrate by a plurality of solder connectors, wherein the plurality of solder connectors extends through the solder resist; and a plurality of spacer connectors physically spacing the package substrate apart from the package. A diameter of a spacer connector of the plurality of spacer connectors is larger than a height of a solder connector of the plurality of solder connectors, and the plurality of spacer connectors is disposed at least in corner regions of the package substrate in a plan view. The package further includes an underfill surrounding the plurality of solder connectors and the plurality of spacer connectors. In some embodiments, the plurality of spacer connectors is further disposed at a center of the package substrate in the plan view. In some embodiments, each of the plurality of spacer connectors comprises a rubber ball, a copper-cored ball, or a plastic ball. In some embodiments, the plurality of spacer connectors extends through the solder resist.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
bonding a first package component to a second package component, wherein bonding the first package component to the second package component comprises bonding first functional connectors on a first surface of the first package component to second functional connectors on a second surface of the second package component while a spacer connector is disposed between the first surface of the first package component and the second surface of the second package component, wherein the spacer connector has a different material composition than the first functional connectors and the second functional connectors; and
dispensing an underfill material between the first package component and the second package component, wherein the underfill material surrounds the first functional connectors and the second functional connectors.

2. The method of claim 1, wherein the spacer connector comprises a copper-cored ball, a plastic ball, or a rubber ball.

3. The method of claim 1, further comprising attaching the spacer connector to the first surface of the first package component by an adhesive material prior to bonding the first package component to the second package component.

4. The method of claim 1, wherein prior to bonding the first package component to the second package component, the method further comprises:
forming the first functional connectors on first function contact pads of the first package component; and
attaching the spacer connector to a dummy contact pad of the first package component.

5. The method of claim 4, wherein the first function connectors are solder connectors, wherein the spacer connector comprises a solder coating, and wherein forming the first functional connectors on the first functional contact pads and attaching the spacer connector to the dummy contact pad comprises a reflow process.

6. The method of claim 5, further comprising flattening upper portions of the first functional contact pads during the reflow process.

7. The method of claim 1, wherein a vertical spacing between the first package component and the second package component is at least partially maintained at a predetermined height by the spacer connector while bonding the first package component to the second package component.

8. The method of claim 1, wherein the underfill material further surrounds the spacer connector.

9. The method of claim 1, wherein the spacer connector is disposed in a corner region between the first package component and the second package component in a plan view.

10. The method of claim 1, wherein the spacer connector is disposed in a center region between the first package component and the second package component in a plan view.

11. A method comprising:
bonding a first die to a first surface of a redistribution structure;
forming first functional connectors on a second surface of the redistribution structure that is opposite to the first surface of the redistribution structure, wherein the first functional connectors are electrically connected to the first die by the redistribution structure; and
attaching a spacer connector to the second surface of the redistribution structure, wherein the spacer connector has larger height than the first functional connectors, and wherein the spacer connector is electrically isolated from the redistribution structure.

12. The method of claim 11, wherein the second surface of the redistribution structure is a surface of a dielectric layer, wherein the first functional connectors are attached to the surface of the dielectric layer by an adhesive.

13. The method of claim 11, wherein the first functional connectors comprise an under bump metallurgy (UBM), wherein a diameter of the spacer connector is greater than a width of the UBM.

14. The method of claim 11, wherein the spacer connector comprises a copper-cored ball, a plastic ball, or a rubber ball.

15. The method of claim 11, further comprising bonding the first functional connectors to a package substrate, wherein the spacer connector extends from the second surface of the redistribution structure to the package substrate.

16. The method of claim 15 further comprising bonding the spacer connector to a dummy contact pad of the package substrate.

17. A method comprising:
providing a first package component, the first package component comprising:
a first die bonded to a first surface of a redistribution structure;
first functional connectors on a second surface of the redistribution structure that is opposite to the first surface of the redistribution structure, wherein the first functional connectors are electrically connected to the first die by the redistribution structure, and wherein the first functional connectors comprise solder; and
adhering a spacer connector to the second surface of the redistribution structure, wherein the spacer connector comprises a core material and a solder coating over the core material, and wherein the spacer connector is electrically isolated from the redistribution structure; and
bonding the first package component to a second package component, wherein the first functional connectors are bonded to second functional connectors of the second package component, and wherein the spacer connector is bonded to a dummy contact pad of the second package component.

18. The method of claim 17 further comprising dispensing an underfill around the first functional connectors and the spacer connector.

19. The method of claim 17, wherein the spacer connector extends further past the second surface of the redistribution structure than the first functional connectors.

20. The method of claim 17, wherein the spacer connector is disposed in a corner region of the first package component in a plan view.
